(19) United States
(12) Patent Application Publication
(10) Pub. No.: US 2007/0063302 A1
(43) Pub. Date: Mar. 22, 2007

(54) Electronic assembly that includes pads having a bowl shaped upper section

(75) Inventors: Chee Koang Chen, Penang (MY); Chi Chyang Siah, Kuala Lumpur (MY); Teik Hong Chuan, Georgetown (MY)

Correspondence Address: SCHWEGMAN, LUNDBERG, WOESSNER & KLUTH, P.A., P.O. BOX 2938, MINNEAPOLIS, MN, 55402, US

(73) Assignee: Intel Corporation

(21) Appl. No.: 11/230,772

(22) Filed: Sep. 20, 2005

(51) Int. Cl. H01L 31/00

(52) U.S. Cl. 257/459

(57) ABSTRACT

Some embodiments relate to an electronic assembly that includes a substrate and a plurality of pads. Each of the pads includes a lower section that is embedded in the substrate and a bowl-shaped upper section that is on top of the lower section. The bowl-shaped upper section protrudes from the substrate such that the bowl-shaped upper section is adapted to be soldered to balls or pads on another electronic assembly (e.g., an electronic package that include a die). Other embodiments relate to a method that includes forming a plurality of pads on a substrate such that each of the pads includes a lower section that is embedded in the substrate and an upper section that protrudes from the substrate. The method further includes heating the plurality of pads and engaging a member with the plurality of pads to form the upper section of each pad into a bowl shape.

### TECHNICAL FIELD

Some example embodiments of the present invention concern electronics packaging, and more particularly, to an electronic assembly that includes pads which have a bowl shaped upper section.

### BACKGROUND

The current paths in electronic assemblies that include processors are continually being required to handle ever-increasing amounts of current in order to power the processors. Processors typically require more power in order to operate at higher frequencies and to simultaneously perform numerous logic and memory operations. As processor power densities continue to increase, so too does the structural challenge of adhering electronic packages that include dies to a substrate (e.g., a motherboard).

One example method of attaching a die to a substrate includes soldering the die to the substrate. An underfill is then injected between the die and the substrate. Capillary flow causes the underfill to seal the area between the die and the substrate that is not occupied by the soldered areas of connection.

Another example method of attaching a die to a substrate includes thermal compression bonding (TCB) the die to the substrate. A typical TCB process includes covering solder balls on a substrate with an underfill and then positioning solder balls on a chip against the solder balls on the substrate. Heat and force are simultaneously applied to the solder balls to cause simultaneous solder interconnect reflow and underfill cure. One of the advantages of TCB over a conventional capillary flow process is that the extra processing steps that are associated with a capillary flow process (e.g., flux application, flux residue cleaning and secondary thermal curing of the underfill) are eliminated.

One of the processing disadvantages that is typically associated with soldering a die to a substrate is that the die can be become misaligned relative to the substrate as it is placed near the substrate for bonding. If the amount of misalignment is large enough, the die bumps can end up having no physical contact with corresponding substrate bumps that are supposed to be joined to the dies bumps. When a die bump fails to physically contact an appropriate substrate bump there can be no wetting between the die bump and the substrate bump.

The substrate and die bumps are typically quite small such that there is little margin for error when the die placed near the substrate for bonding. Therefore, it would be desirable to increase the acceptable tolerance that is associated with placing the die near the substrate for bonding.

### BRIEF DESCRIPTION OF THE DRAWINGS

FIG. 1 is a side section view that illustrates a portion of an example electronic assembly which includes a substrate and a plurality of pads.

FIG. 2 is a top view of the electronic assembly shown in FIG. 1.

FIG. 3 is a top view similar to FIG. 2 illustrating another example embodiment for the electronic assembly shown in FIG. 1.

FIG. 4 is a top view similar to FIGS. 2 and 3 illustrating another example embodiment for the electronic assembly shown in FIG. 1.

FIG. 5 is a side section view that illustrates a portion of an example electronic assembly which includes a die and a plurality of pads.

FIG. 6 is a top view of the electronic assembly shown in FIG. 5.

FIG. 7 is a top view similar to FIG. 6 illustrating another example embodiment for the electronic assembly shown in FIG. 5.

FIG. 8 is a top view similar to FIGS. 6 and 7 illustrating another example embodiment for the electronic assembly shown in FIG. 5.

FIG. 9 is a flow diagram illustrating an example method of fabricating a substrate.

FIG. 10 shows an example substrate before pads on the substrate are engaged by a member.

FIG. 11 shows the substrate of FIG. 10 after the pads on the substrate have been engaged by the member.

FIG. 12 is a flow diagram illustrating an example method of fabricating an electronic package.

### DETAILED DESCRIPTION

The following detailed description references the accompanying drawings. Like numerals describe substantially similar components throughout each of the drawings. Other embodiments may be used, and structural, logical, and electrical changes made. The integrated circuit described herein can be manufactured, used, or shipped in a number of positions and orientations.

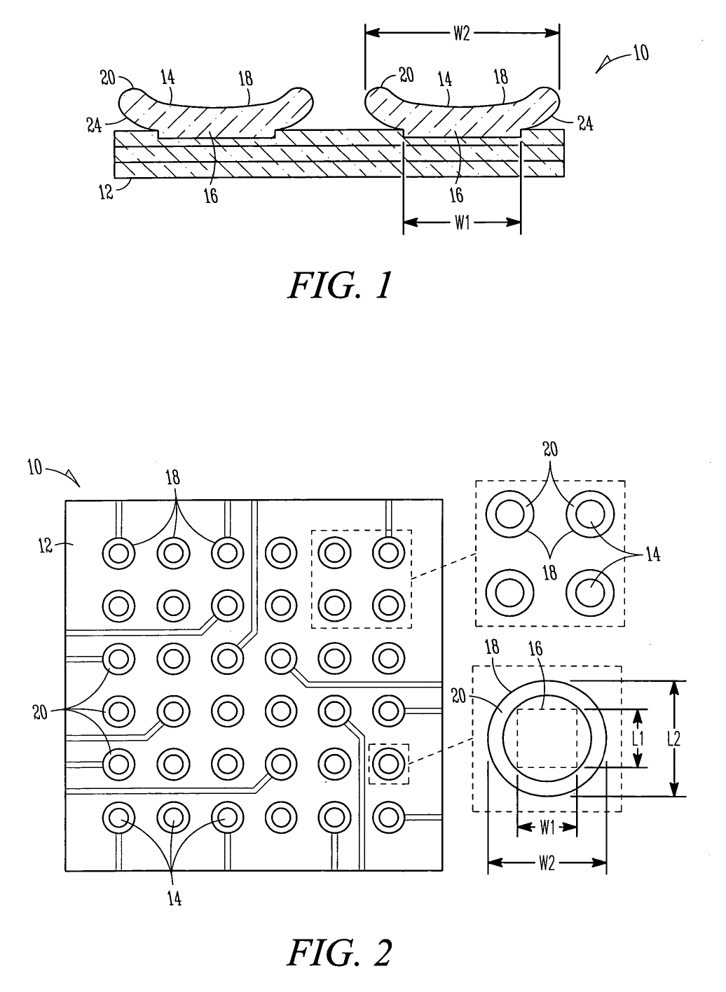

FIG. 1 is a side section view that illustrates a portion of an electronic assembly 10 which includes a substrate 12 and a plurality of pads 14. Each of the pads 14 includes a lower section 16 that is embedded in the substrate 12 and a bowl-shaped upper section 18 that is on top of the lower section 16. The bowl-shaped upper section 18 protrudes from the substrate 12 such that the bowl-shaped upper section 18 is adapted to be bonded to balls or pads on another electronic assembly (e.g., an electronic package that include a die).

In some embodiments, substrate 12 may be a motherboard. In addition, substrate 12 may be made of a semiconducting, non-semiconducting, or combinations of semiconducting and non-semiconducting materials. The substrate 12 may be formed of one layer or multiple layers as shown in FIG. 1. In addition, the substrate 12 may include conductive traces that electrically connect the pads 14 to one another or to other electronic components.

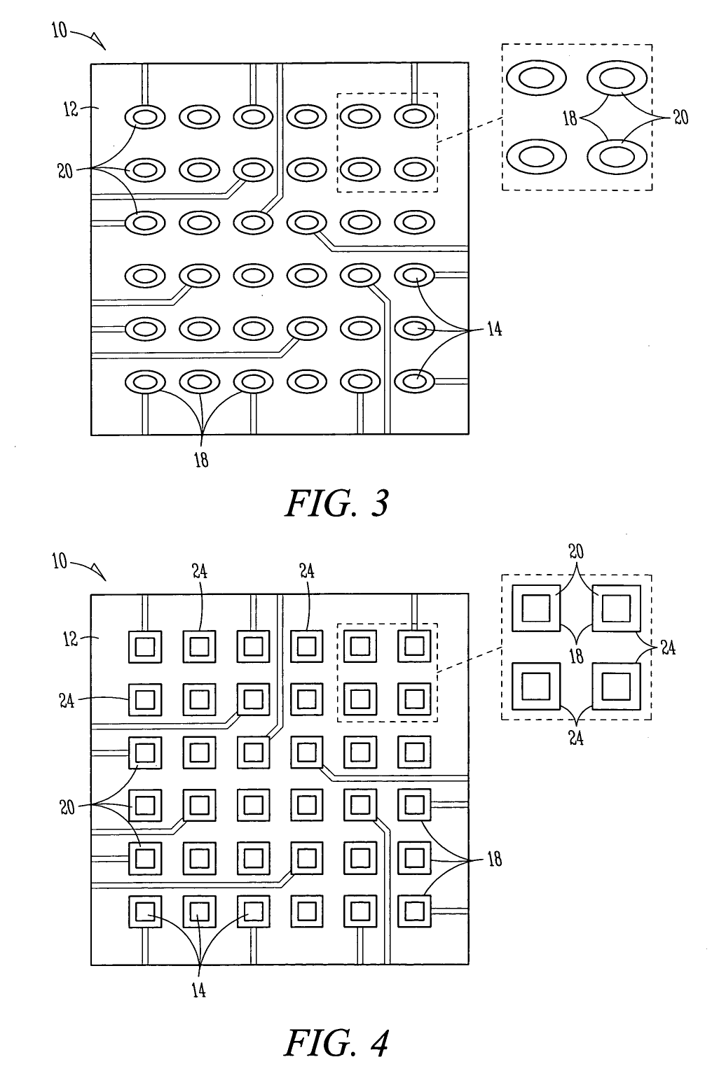

FIG. 2 is a top view of the electronic assembly shown in FIG. 1. Although each of the bowl-shaped upper sections 18 are shown as including a circular upper surface 20, the upper surface 20 may have a variety of shapes. As examples, FIG. 3 shows an embodiment where the upper surface 20 of the bowl-shaped upper sections 18 has an oval shape and FIG. 4 shows an embodiment where the upper surface 20 of the bowl-shaped upper sections 18 has a predominately square shape. It should be noted that the upper surface 20 each bowl-shaped upper section 18 may be any size, shape or geometry that facilitates bonding the substrate 12 to another electronic device.

As shown most clearly in FIG. 2, the lower section 16 of each pad 14 may have a first width W1 and the bowl-shaped upper section 18 of each pad 14 may have a second width W2 that is greater than first width W1. In addition, the lower section 16 of each pad 14 may have a first length L1 and the bowl-shaped upper section 18 of each pad 14 may have a second length L2 that is greater than first length L1.

Although each of the bowl-shaped upper sections 18 are shown in FIG. 1 as including a rounded outer surface 24, the outer surface 24 may have a variety of shapes. As an example, FIG. 4 shows an example embodiment where the outer surface 24 of each bowl-shaped upper section 18 may have flat sides that form a square shape. It should be noted that the outer surface 24 of each bowl-shaped upper section 18 may be any size, shape or geometry that facilitates bonding the substrate 12 to another electronic device (e.g., elliptical, square, rectangular or hexagonal shapes).

The lower section 16 of each pad 14 may also be any size, shape or geometry. In addition, the lower section 16 of each pad 14 may be wholly embedded in the substrate 12 or partially embedded in the substrate 12 such that a portion of the lower section 16 protrudes from the substrate 12. The size, shape and geometry of the lower sections 16 on each pad 14 may depend in part on manufacturing considerations and the application where the electronic assembly 10 will be used (among other factors).

The upper sections 18 of each pad 16 may make it easier to compensate for some of the processing disadvantages that are typically associated with bonding a substrate 12 to an electronic device (e.g., a die). As discussed above, a die can be become misaligned relative to a substrate 12 as it is placed near the substrate 12 for bonding. If a die bump fails to physically contact an appropriate pad 14 on the substrate 12 no wetting occurs between the die bump and a corresponding pad 14.

The upper sections 18 of each pad 16 may serve to increase the acceptable tolerance that is associated with placing the die near the substrate 12 for bonding. Therefore, the die bumps may be more likely to wet the pads 14 on the substrate 12.

The upper and lower sections 16, 18 of each pad 14 may be made from the same material or different materials. Some example materials for upper and lower sections 16, 18 of each pad 14 include gold, silver, copper, tin, solder and alloys comprised of any combination of tin, bismuth, lead and/or indium. The types of materials that are selected for the upper section 18 and the lower section 16 will depend on manufacturing considerations and the application where the electronic assembly 10 is to be used.

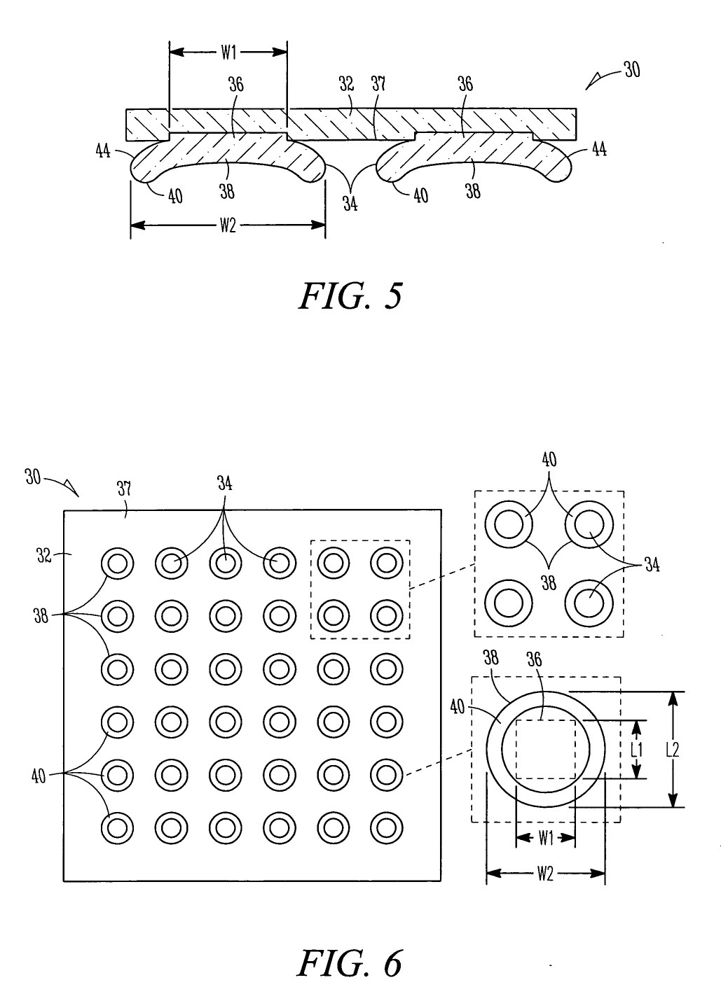

FIG. 5 is a side section view that illustrates a portion of an electronic assembly 30 which includes a die 32 and a plurality of pads 34. Each of the pads 34 includes a lower section 36 that is embedded in the die 32 and a bowl-shaped upper section 38 that extends from the lower section 36. The bowl-shaped upper section 38 extends from the lower section 36 such that the bowl-shaped upper section 38 is adapted to be bonded to balls or pads on another electronic assembly (e.g., a substrate).

Although it is not clearly illustrated in FIG. 5, the die 32 may be part of an electronic package. The size, type and alignment of the electronic package may vary depending on the design of electronic assembly 30. The components that make up electronic assembly 30 will be determined based on the space available and the application where electronic assembly 30 is to be used (among other factors). In addition, the die 32 may be at least partially encapsulated by a protective material.

Die 32 may be made of a material that has been separated from a wafer. Wafers may be made of semiconducting, non-semiconducting, or combinations of semiconducting and non-semiconducting materials.

It should be noted that die 32 may be a processor of any type. As used herein, processor means any type of circuit such as, but not limited to, a microprocessor, a microcontroller, a graphics processor or a digital signal processor. Die 32 may also be a custom circuit or an application-specific integrated circuit, such as a communications circuit for use in wireless devices such as cellular telephones, pagers, portable computers, two-way radios, and similar electronic systems.

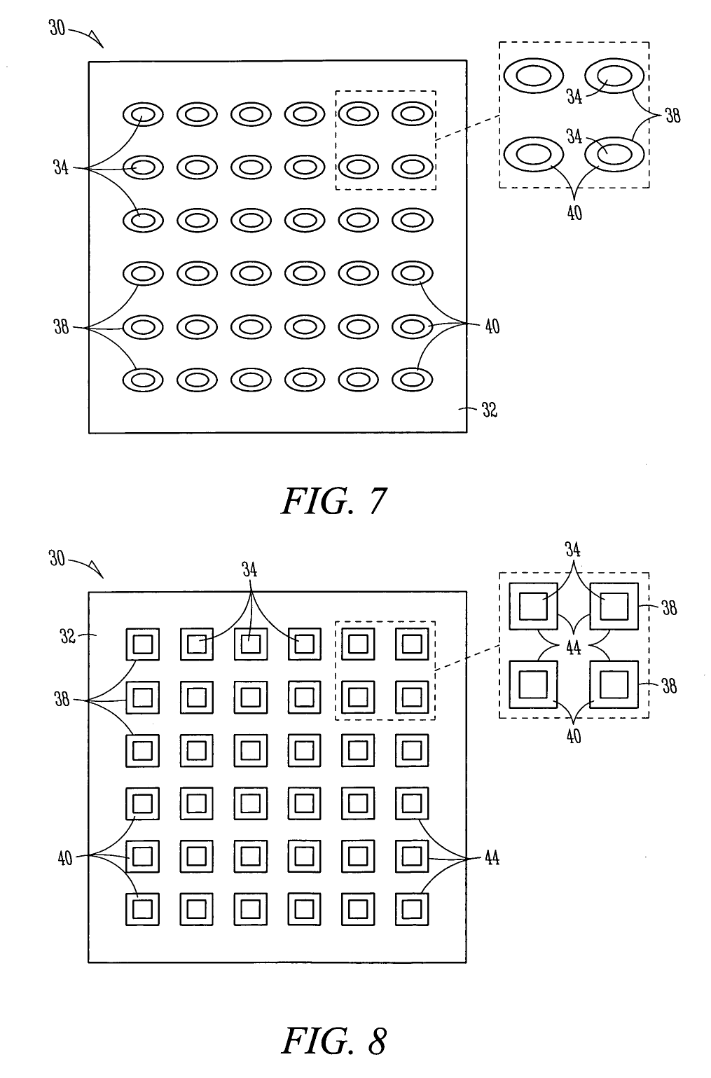

FIG. 6 is a top view of the electronic assembly 30 shown in FIG. 5. Although each of the bowl-shaped upper sections 38 are shown as including a rounded upper surface 40, the upper surface 40 may have a variety of shapes. As examples, FIG. 7 shows an embodiment where the upper surface 40 of the bowl-shaped upper sections 38 has an oval shape and FIG. 8 shows an embodiment where the upper surface 40 of the bowl-shaped upper sections 38 has a predominately square shape. It should be noted that the upper surface 40 may be any size, shape or geometry that facilitates bonding the die 32 to another electronic device.

As shown most clearly in FIG. 6, the lower section 36 of each pad 34 may have a first width W1 and the bowl-shaped upper section 38 of each pad 34 may have a second width W2 that is greater than first width W1 (see also FIG. 5). In addition, the lower section 36 of each pad 34 may have a first length L1 and the bowl-shaped upper section 38 of each pad 34 may have a second length L2 that is greater than first length L1.

Although each of the bowl-shaped upper sections 38 are shown in FIG. 5 as including a spherical outer surface 44, the outer surface 44 may have a variety of shapes. As an example, FIG. 8 shows an embodiment where the outer surface 44 may have flat sides that form a square shape. It should be noted that the outer surface 44 may be any size, shape or geometry that facilitates bonding the die 32 to another electronic device (e.g., rectangular or hexagonal shapes).

The lower section 36 of each pad 34 may also be any size, shape or geometry. In addition, the lower section 36 of each pad 34 may be wholly embedded in the die 32, or partially embedded in the die 32 such that a portion of the lower section 36 protrudes from the die 32. In some embodiments, the lower section 36 may be positioned on a surface 37 of the die 32. The size, shape and geometry of the lower sections 36 on each pad 34 may depend in part on manufacturing considerations and the application where the electronic assembly 30 will be used (among other factors).

The upper sections 38 of each pad 34 may make it easier to compensate for some of the processing drawbacks that are typically associated with bonding a die 32 to an electronic device (e.g., a substrate). As discussed above, a die 32 can become misaligned relative to a substrate as it is placed near the substrate for bonding.

If there is enough misalignment between a die 32 and a substrate, one or more pads 34 on the die 32 may fail to physically contact an appropriate bump on the substrate such that no wetting occurs between the pads 34 and the corresponding bumps on the substrate. The upper sections 38 of each pad 34 may serve to increase the acceptable tolerance that is associated with placing the die 32 near the substrate for bonding.

The upper and lower sections 36, 38 of each pad 34 may be made from the same material or different materials. Some example materials for upper and lower sections 36, 38 of each pad 34 include gold, silver, copper, tin, solder and alloys comprised of any combination of tin, bismuth, lead and/or indium. The types of materials that are selected for the upper section 38 and the lower section 36 will depend on manufacturing considerations and the application where the electronic assembly 30 is to be used.

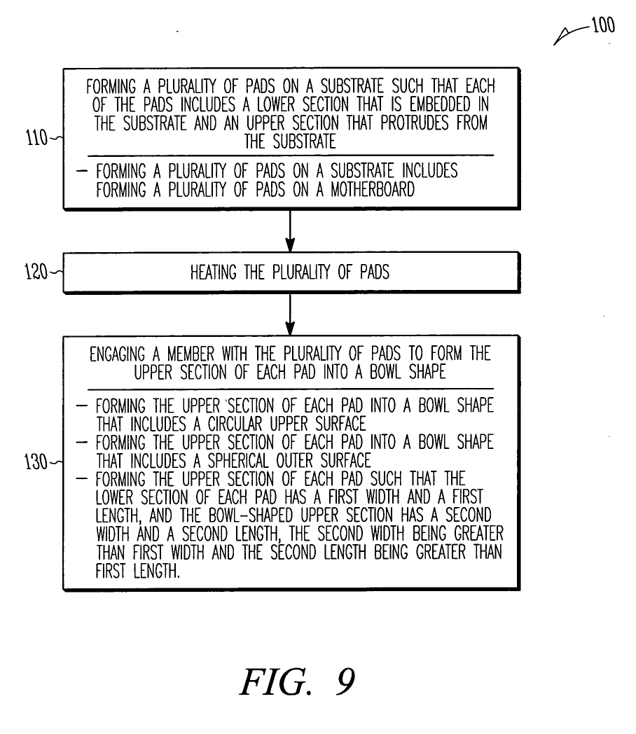

FIG. 9 illustrates an example method 100 that includes 110 forming a plurality of pads on a substrate such that each of the pads includes a lower section that is embedded in the substrate and an upper section that protrudes from the substrate. The method further includes 120 heating the plurality of pads and 130 engaging a member with the plurality of pads to form the upper section of each pad into a bowl shape.

In some embodiments, 110 forming a plurality of pads on a substrate may include forming a plurality of pads on a motherboard. In addition, 130 engaging a member with the plurality of pads may include (i) forming the upper section of each pad into a bowl shape that includes a circular upper surface; and/or (ii) forming the upper section of each pad into a bowl shape that includes a spherical outer surface.

It should be noted that 130 engaging a member with the plurality of pads may include forming each pad such that the lower section of each pad has a first width and a first length and the bowl-shaped upper section of each pad has a second width and a second length. The bowl-shaped upper section may be formed such that the second width of the bowl-shaped upper section is greater than the first width of the lower section and the second length of the bowl-shaped upper section is greater than the first length of the lower section.

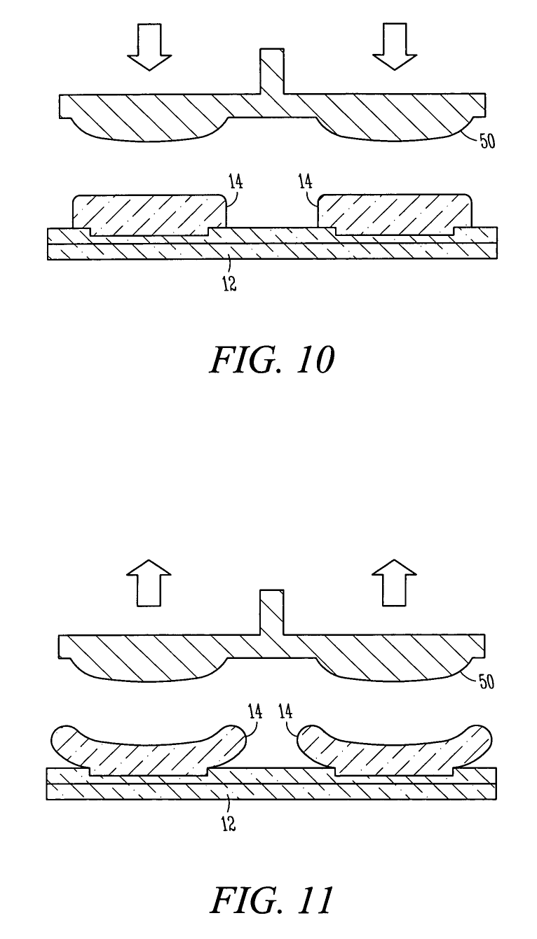

FIG. 10 shows an example substrate 12 before pads 14 on the substrate 12 are engaged by a member 50. FIG. 11 shows the substrate 12 of FIG. 10 after the pads 14 on the substrate 12 have been engaged by a member 50.

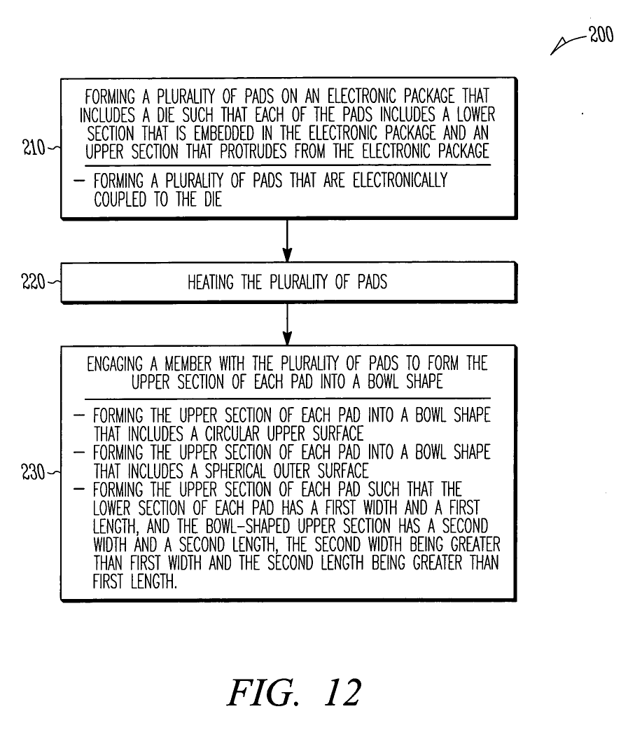

FIG. 12 illustrates an example method 200 that includes 210 forming a plurality of pads on an electronic package that includes a die such that each of the pads includes a lower section that is embedded in the electronic package and an upper section that protrudes from the electronic package. The method further includes 220 heating the plurality of pads and 230 engaging a member with the plurality of pads to form the upper section of each pad into a bowl shape.

In some embodiments, 210 forming a plurality of pads on an electronic package that includes a die may include forming a plurality of pads that are electrically coupled to the die. In addition, 230 engaging a member with the plurality of pads may include (i) forming the upper section of each pad into a bowl shape that includes a circular upper surface; and/or (ii) forming the upper section of each pad into a bowl shape that includes a spherical outer surface.

It should be noted that 230 engaging a member with the plurality of pads may include forming each pad such that the lower section of each pad has a first width and a first length and the bowl-shaped upper section of each pad has a second width and a second length. The bowl-shaped upper section may be formed such that the second width of the bowl-shaped upper section is greater than the first width of the lower section and the second length of the bowl-shaped upper section is greater than the first length of the lower section.

The methods and electronic assemblies described herein may be implemented in a number of different embodiments, including an electronic package, an electronic system, a computer system, and one or more methods of fabricating an electronic assembly. The elements, materials, geometries, dimensions, and sequence of operations can all be varied to suit particular packaging requirements.

FIGS. 1-12 are merely representational and are not drawn to scale. Certain proportions thereof may be exaggerated while others may be minimized.

The electronic assembly described above may provide a solution for bonding an electronic package to a motherboard. Many other embodiments will be apparent to those of skill in the art after reviewing the above detailed description.

What is claimed:

1. An electronic assembly comprising:
a substrate; and
a plurality of pads, each of the pads including a lower section that is embedded in the substrate and a bowl-shaped upper section that is on top of the lower section such that the bowl-shaped upper section protrudes from the substrate.

2. The electronic assembly of claim 1 wherein the substrate is a motherboard.

3. The electronic assembly of claim 1 wherein each of the bowl-shaped upper sections includes a circular upper surface.

4. The electronic assembly of claim 1 wherein the lower section of each pad has a first width and the bowl-shaped upper section of each pad has a second width, the second width being greater than first width.

5. The electronic assembly of claim 4 wherein the lower section of each pad has a first length and the bowl-shaped upper section of each pad has a second length, the second length being greater than first length.

6. The electronic assembly of claim 1 wherein each of the bowl-shaped upper sections includes a rounded outer surface.

7. An electronic assembly comprising:
an electronic package that includes a die; and
a plurality of pads, each of the pads including a lower section that is embedded in the electronic package and a bowl-shaped upper section that is on top of the lower section such that the bowl-shaped upper section protrudes from the electronic package.

8. The electronic assembly of claim 7 wherein the die is a processor.

9. The electronic assembly of claim 7 wherein each of the bowl-shaped upper sections includes a circular upper surface.

10. The electronic assembly of claim 7 wherein the lower section of each pad has a first width and the bowl-shaped upper section of each pad has a second width, the second width being greater than first width.

11. The electronic assembly of claim 10 wherein the lower section of each pad has a first length and the bowl-shaped upper section of each pad has a second length, the second length being greater than first length.

12. The electronic assembly of claim 7 wherein each of the bowl-shaped upper sections includes a rounded outer surface.

13. A method comprising:
forming a plurality of pads on a substrate such that each of the pads includes a lower section that is embedded in the substrate and an upper section that protrudes from the substrate;
heating the plurality of pads; and
engaging a member with the plurality of pads to form the upper section of each pad into a bowl shape.

14. The method of claim 13 wherein forming a plurality of pads on a substrate includes forming a plurality of pads on a motherboard.

15. The method of claim 13 wherein engaging a member with the plurality of pads includes forming the upper section of each pad into a bowl shape that includes a circular upper surface.

16. The method of claim 13 wherein engaging a member with the plurality of pads includes forming the upper section of each pad into a bowl shape that includes a rounded outer surface.

17. The method of claim 13 wherein engaging a member with the plurality of pads includes forming the upper section of each pad such that the lower section of each pad has a first width and a first length, and the bowl-shaped upper section has a second width and a second length, the second width being greater than first width and the second length being greater than first length.

18. A method comprising:
forming a plurality of pads on an electronic package that includes a die such that each of the pads includes a lower section that is embedded in the electronic package and an upper section that protrudes from the electronic package;
heating the plurality of pads; and
engaging a member with the plurality of pads to form the upper section of each pad into a bowl shape.

19. The method of claim 18 wherein forming a plurality of pads on the electronic package includes forming a plurality of pads that are electrically coupled to the die.

20. The method of claim 18 wherein engaging a member with the plurality of pads includes forming the upper section of each pad into a bowl shape that includes a circular upper surface.

21. The method of claim 18 wherein engaging a member with the plurality of pads includes forming the upper section of each pad into a bowl shape that includes a rounded outer surface.

22. The method of claim 18 wherein engaging a member with the plurality of pads includes forming the upper section of each pad such that the lower section of each pad has a first width and a first length, and the bowl-shaped upper section has a second width and a second length, the second width being greater than first width and the second length being greater than first length.
